(19) United States
(12) Patent Application Publication
(10) Pub. No.: US 2023/0156994 A1
(43) Pub. Date: May 18, 2023

(54) APPARATUS FOR REPAIRING ELEMENT

(71) Applicant: CENTER FOR ADVANCED META-MATERIALS, Daejeon (KR)

(72) Inventors: Kwang Seop KIM, Daejeon (KR); Chan KIM, Daejeon (KR); Min Ah YOON, Seoul (KR); Bong Kyun JANG, Daejeon (KR); Min Sub OH, Seoul (KR); Jae Hyun KIM, Daejeon (KR); Hyung Jun LIM, Daejeon (KR); Se Jeong WON, Daejeon (KR); Hak Joo LEE, Daejeon (KR)

(73) Assignee: CENTER FOR ADVANCED META-MATERIALS, Daejeon (KR)

(21) Appl. No.: 18/093,333

(22) Filed: Jan. 5, 2023

Related U.S. Application Data
(63) Continuation of application No. PCT/KR2021/011645, filed on Aug. 31, 2021.

(30) Foreign Application Priority Data
Aug. 31, 2020 (KR) 10-2020-0110491

(51) Int. Cl. H05K 13/04; H05K 3/34; B23K 37/04

(52) U.S. Cl. CPC H05K 13/0486; H05K 3/34; B23K 37/0408; B23K 2101/42

(57) ABSTRACT

An apparatus for repairing elements, includes: a bonding material transfer stamp transferring a new bonding material to a repair area on a substrate, the repair area having a defective element or a residual bonding material removed therefrom; and an element transfer stamp transferring a new element to the new bonding material, wherein the element transfer stamp comprises a load control portion for elements, the load control portion being bent and deformed upon receiving pressing force such that a zero-stiffness load smaller than a critical damage load of the new element is applied to the new element.

### TECHNICAL FIELD

The present invention relates to an apparatus for repairing elements, which can prevent damage to a new element during transfer of the new element and can ensure a safe repair process.

### BACKGROUND ART

In general, an element module including multiple elements mounted on a substrate undergoes testing to inspect defective elements, and a process of removing an element determined to be defective and replacing the element with a new element is called a repair process.

Repair devices used in the repair process include a device for separating a defective element from a substrate by melting a solder on the defective element, a device for mounting a new element on the substrate, and the like.

However, a conventional element repair process has a problem in that excessive pressure can be applied to a new element during transfer of the new element, causing damage to the new element. In addition, in order to prevent this problem, various types of sensors are required to measure the pressure applied to elements or to monitor the condition of elements, which results in a complicated apparatus configuration.

Further, there is a problem that, during removal of a defective element or transfer of a new element, other normal elements separate from the defective element are likely to be damaged.

Recently, with development of nanotechnology, the size of elements has become smaller and smaller. However, a conventional apparatus for repairing elements is difficult to use for microelements due to the physical size of a vacuum suction tool. Therefore, there is a need for element repair technology that can effectively remove a defective microelement from a substrate having multiple microelements arranged thereon and can reliably replace the defective microelement with a new microelement.

### DISCLOSURE

### Technical Problem

Embodiments of the present invention are conceived to solve such problems in the art and it is an object of the present invention to provide an apparatus for repairing elements, which can prevent damage to a new element during transfer of the new element and can ensure a safe repair process.

It will be understood that objects of the present invention are not limited to the above.

The above and other objects of the present invention will become apparent to those skilled in the art from the detailed description of the following embodiments in conjunction with the accompanying drawings

Technical Solution

In accordance with one aspect of the present invention, an apparatus for repairing elements includes: a bonding material transfer stamp transferring a new bonding material to a repair area on a substrate, the repair area having a defective element or a residual bonding material removed therefrom; and an element transfer stamp transferring a new element to the new bonding material, wherein the element transfer stamp includes a load control portion for elements, the load control portion being bent and deformed upon receiving pressing force such that a zero-stiffness load smaller than a critical damage load of the new element is applied to the new element.

In one embodiment, the apparatus for repairing elements may further include: a removal stamp removing a defective element on a substrate and a residual bonding material remaining after removal of the defective element.

In one embodiment, the removal stamp may include: multiple pads contacting the defective element, one of the multiple pads being selected to be adhesively attached to the defective element.

In one embodiment, the removal stamp may further include: a tape having a lower surface to which the multiple pads are attached in a row, the tape being fed by a pair of rollers spaced apart from each other and connected to the tape; and a pressing head disposed on an upper surface of the tape to be vertically movable and pressing the tape downward to press one of the multiple pads against the defective element.

In one embodiment, the removal stamp may include: an attachment film having a lower surface to which the multiple pads are attached in the form of an array; and a pressing rod disposed above the attachment film to be horizontally/vertically movable and pressing the attachment film downward to press one of the multiple pads against the defective element.

In one embodiment, the pad may include: a receiving groove formed on a lower surface of the pad to receive the defective element therein; a heater disposed around the receiving groove; and an adhesive layer disposed in the receiving groove and heated by the heater to allow the defective element received in the receiving groove to be adhesively attached to the adhesive layer.

In one embodiment, the heater may be an induction heater inductively heating a bonding material electrically connecting the defective element to the substrate.

In one embodiment, the removal stamp may further include: a load control portion for removal, the load control portion being bent and deformed upon receiving pressing force such that a zero-stiffness load smaller than a critical damage load of the defective element is applied to the defective element.

In one embodiment, the element transfer stamp may further include: a fluid inlet through which a fluid supplied from an exterior passes; an elastic layer inflated downward by the fluid introduced through the fluid inlet, the elastic layer having adhesive strength; and a flow rate control portion controlling a flow rate of the fluid through the fluid inlet to regulate adhesion between the elastic layer and the new element.

In one embodiment, the apparatus for repairing elements may further include: a reflow stamp bonding the new element to the new bonding material by pressing and heating the new element, wherein the reflow stamp may include a pressure heater heating the new element and the new bonding material while pressing the new element and a buffer layer disposed around the pressure heater, the buffer layer being brought into close contact with elements around the new element when the pressure heater presses the new element.

In one embodiment, the reflow stamp may further include: a load control portion for reflow, the load control portion being bent and deformed upon receiving pressing force such that a zero-stiffness load smaller than a critical damage load of the new element is applied to the new element.

In one embodiment, the bonding material transfer stamp may further include: a tape having a lower surface to which multiple new bonding materials are attached in a row, the tape being fed by a pair of rollers spaced apart from each other and connected to the tape; and a pressing head disposed on an upper surface of the tape to be vertically movable and pressing the tape downward to press one of the multiple new bonding materials against the repair area.

In one embodiment, the bonding material transfer stamp may further include: an attachment film having a lower surface to which multiple new bonding materials are attached in the form of an array; and a pressing rod disposed above the attachment film to be horizontally/vertically movable and pressing the attachment film downward to press one of the multiple new bonding materials against the repair area.

In one embodiment, the element transfer stamp may further include: a tape having a lower surface to which multiple new elements are attached in a row, the tape being fed by a pair of rollers spaced apart from each other and connected to the tape; and a pressing head disposed on an upper surface of the tape to be vertically movable and pressing the tape downward to press one of the multiple new elements against the new bonding material.

In one embodiment, the element transfer stamp may further include: an attachment film having a lower surface to which multiple new elements are attached in the form of an array; and a pressing rod disposed above the attachment film to be horizontally/vertically movable and pressing the attachment film downward to press one of the multiple new elements against the new bonding material.

### Advantageous Effects

According to embodiments of the present invention, an element transfer stamp transferring a new element to a new bonding material includes a load control portion for elements, the load control portion being bent and deformed upon receiving pressing force such that a zero-stiffness load smaller than a critical damage load of the new element is applied to the new element, thereby preventing damage to a new element during transfer of the new element.

It will be understood that advantageous effects of the present invention are not limited to the above and include any advantageous effects conceivable from the features disclosed in the detailed description of the present invention or the appended claims.

### DESCRIPTION OF DRAWINGS

FIG. 1 is a schematic view of an apparatus for repairing elements according to a first embodiment of the present invention, focusing on a bonding material transfer stamp thereof

FIG. 2 is a schematic view of the apparatus for repairing elements according to the first embodiment of the present invention, focusing on an element transfer stamp thereof.

FIG. 3 is a schematic view illustrating an exemplary operation of the element transfer stamp of FIG. 2.

FIG. 4 is a view illustrating deformation of a load control portion for elements of FIG. 3 and a graph of the resulting displacement-load relation.

FIG. 5 is a schematic view illustrating an example of the element transfer stamp of FIG. 2.

FIG. 6 is a schematic view of another example of the element transfer stamp of FIG. 2.

FIG. 7 is a schematic view of the apparatus for repairing elements according to the first embodiment of the present invention, focusing on a reflow stamp thereof

FIG. 8 is a schematic view of an apparatus for repairing elements according to a second embodiment of the present invention, focusing on a removal stamp thereof.

FIG. 9 is a schematic view of an example of the removal stamp of FIG. 8.

FIG. 10 is a schematic view illustrating an exemplary operation of the removal stamp of FIG. 8.

FIG. 11 is an exemplary view of the pad of FIG. 9.

FIG. 12 is a schematic view illustrating an exemplary operation of the pad of FIG. 11.

FIG. 13 is a schematic view of another example of the removal stamp of FIG. 8.

FIG. 14 is a schematic view illustrating an exemplary operation of the removal stamp of FIG. 13.

### MODE FOR INVENTION

Reference will now be made in detail to various embodiments, examples of which are illustrated in the accompanying drawings. It should be understood that the present invention may be embodied in different ways and is not limited to the following embodiments. In the drawings, portions irrelevant to the description will be omitted for clarity. Like components will be denoted by like reference numerals throughout the specification.

Throughout the specification, when an element or layer is referred to as being “on”, “connected to”, or “coupled to” another element or layer, it may be directly on, connected to, or coupled to the other element or layer or intervening elements or layers may be present. In addition, unless stated otherwise, the term “includes” should be interpreted as not excluding the presence of other components than those listed herein.

The terminology used herein is for the purpose of describing particular embodiments and is not intended to be limiting. As used herein, the singular forms, “a,” “an,” and “the” are intended to include the plural forms as well, unless the context clearly indicates otherwise.

Moreover, the terms “comprises”, “comprising,” “includes.” and/or “including” when used in this specification, specify the presence of stated features, integers, steps, operations, elements, components, and/or groups thereof, but do not preclude the presence or addition of one or more other features, integers, steps, operations, elements, components, and/or groups thereof.

Hereinafter, embodiments of the present invention will be described with reference to the accompanying drawings.

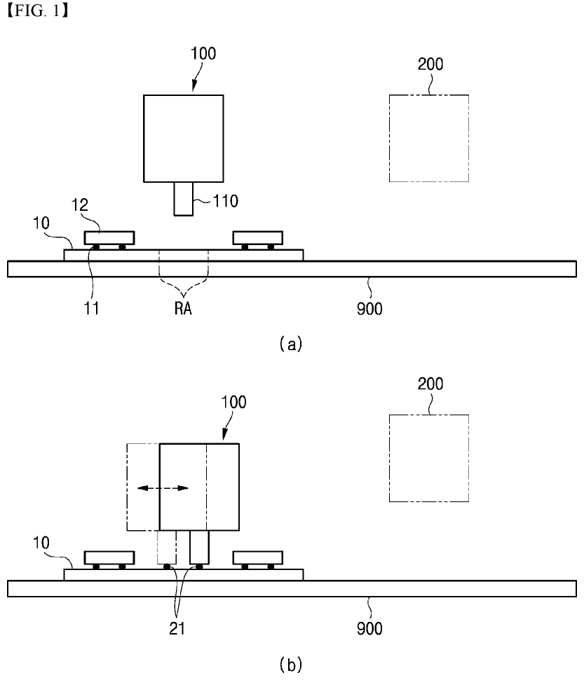

FIG. 1 is a schematic view of an apparatus for repairing elements according to a first embodiment of the present invention, focusing on a bonding material transfer stamp thereof

Referring to FIG. 1, the apparatus for repairing elements may include a bonding material transfer stamp 100 and an element transfer stamp 200.

The bonding material transfer stamp 100 may transfer a new bonding material 21 to a repair area RA on a substrate 10 disposed on a stage 900, wherein the repair area RA is an area from which a defective element or a residual bonding material has been removed.

The stage 900 may be moved in virtual X- and Y-axis directions on a horizontal plane. In addition, the apparatus for repairing elements may further include a vacuum chuck disposed on an upper surface of the stage 900 to prevent slipping between the stage 900 and the substrate 10 during movement of the stage 900. Here, the substrate 10 may be disposed on the vacuum chuck to be movable in conjunction with movement of the stage 900.

The substrate 10 may be a substrate that has undergone an element transfer process. In general, transfer of an element to the substrate 10 may be considered as defective when the element has failed to be transferred to the substrate, when the element transferred to the substrate is not accurately aligned with a bonding material, when damage to the element has occurred, or when electrical connection between the element and the bonding material is poor. The apparatus for repairing elements according to this embodiment may be used when the element has failed to be transferred to the substrate.

The bonding material transfer stamp 100 may transfer a new bonding material 21 to the repair area RA where there is no bonding material placed. Here, the new bonding material 21 may be of the same material as a bonding material 11 already placed on the substrate 10, and may include a flux, a solder paste, an anisotropic conductive film (ACF), an anisotropic conductive paste (ACP), a non-conductive film (NCF), and the like.

The bonding material transfer stamp 100 may include a transfer tip 110 to transfer the new bonding material 21 to the substrate 10. As shown in FIG. 1(b), the bonding material transfer stamp 100 may be configured to be movable in a horizontal direction so as to transfer the new bonding material 21 to the substrate 10. Alternatively, the bonding material transfer stamp 100 may include a large-area transfer tip 110 or a plurality of transfer tips 110 corresponding to the shape in which the new bonding material 21 will be transferred to the substrate 10 so as to transfer the new bonding material 21 to the substrate 10 without moving in the horizontal direction.

In addition, the bonding material transfer stamp 100 may further include a cleaning tip (not shown) to clean an electrode (not shown) on the substrate 10 to which the new bonding material 21 will be transferred.

The element transfer stamp 200 may be disposed to one side of the bonding material transfer stamp 100 and the substrate 10 having the new bonding material 21 transferred thereto may be moved under the element transfer stamp 200 by the stage 900.

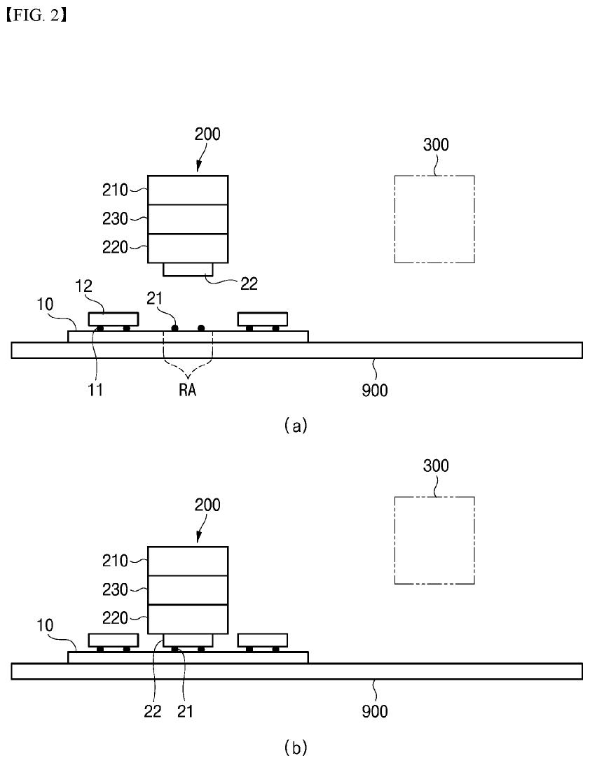

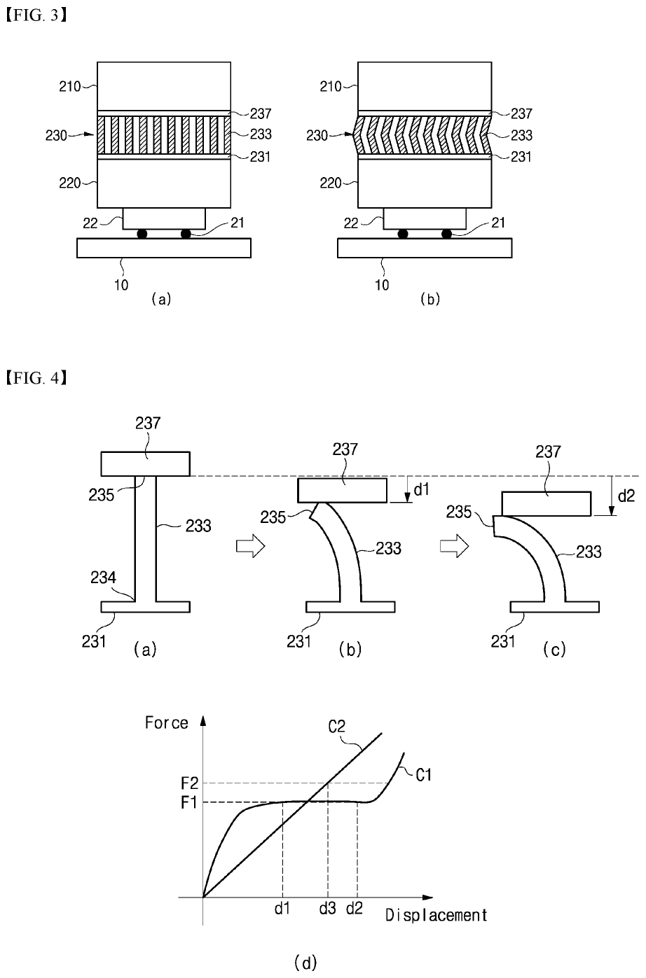

FIG. 2 is a schematic view of the apparatus for repairing elements according to the first embodiment of the present invention, focusing on the element transfer stamp and FIG. 3 is a schematic view illustrating an exemplary operation of the element transfer stamp of FIG. 2.

Referring to FIG. 2 and FIG. 3, the element transfer stamp 200 may transfer a new element 22 to the new bonding material 21.

The element transfer stamp 200 may include a load control portion 230 for elements. The load control portion 230 for elements may be bent and deformed upon receiving pressing force to allow a zero-stiffness load smaller than a critical damage load of the new element 22 to be applied to the new element 22. First, the load control portion 230 for elements will be described in detail.

FIG. 4 is a view illustrating deformation of the load control portion for elements of FIG. 3 and a graph of the resulting displacement-load relation. In FIG. 4(d), a first curve (C1) is a load-displacement curve of the element transfer stamp with the load control portion for elements and a second curve (C2) is a load-displacement curve of a stamp without the load control portion for elements.

Referring to FIG. 4, the load control portion 230 for elements may include a base 231, a pillar 233, and a plate 237.

The base 231 may be formed flat and the pillar 233 may be connected at one end 234 thereof to one surface of the base 231. The plate 237 may adjoin the other end 235 of the pillar 233. Upon application of external force in an axial direction of the pillar 233, the pillar 233 may be bent and deformed. Here, bending deformation of the pillar 233 may include buckling.

In the element transfer stamp 200, the load control portion 230 for elements may be positioned such that external force applied thereto is transferred to the pillar 233 through the plate 237. However, it will be understood that the present invention is not limited thereto and the load control portion 230 for elements may be positioned such that external force applied thereto is transferred to the pillar 233 through the base 231.

Each of the base 231, the pillar 233, and the plate 237 may be formed of at least one selected from among silicone rubber, urethane rubber, fluororubber, ethylene-propylene-diene rubber (EPDM), nitrile-butadiene rubber (NBR), polymethyl methacrylate (PMMA), and a photoresist.

In one embodiment, the load control portion 230 for elements may be directly manufactured through a photolithography process using a UV light source, a 3D printing process, or a LIGA process using X-rays. Here, as a material for the load control portion 230 for elements, at least one selected from among silicone rubber, PMMA, and an epoxy-based negative photoresist may be used.

In another embodiment, the load control portion 230 for elements may be manufactured by a method including: fabricating a mold corresponding in shape to the load control portion 230 for elements through a 3D printing process or a LIGA process; and forming the load control portion for elements by injecting a molding liquid into the mold, followed by curing.

The molding liquid may include at least one selected from among silicone rubber, urethane rubber, fluororubber, EPDM, and NBR. The molding liquid may be cured by room-temperature vulcanization or high-temperature vulcanization.

Referring to FIG. 4, when the pillar 233 is bent and deformed by a first displacement d1 and then further bent and deformed to a second displacement d2 greater than the first displacement d2 by receiving external force through the plate 237, the load control portion 230 for elements according to the present invention may generate a zero-stiffness load F1 within the displacement range from the first displacement d1 to the second displacement d2. That is, the load control portion 230 for elements may have a displacement-load relation having a zero-stiffness zone, in which load generated by the load control portion 230 for elements remains at a constant level F1, over the displacement range from the first displacement d1 to the second displacement d2.

In other words, when the load control portion 230 for elements undergoes compressive deformation by external force, load generated by the load control portion 230 for elements does not increase within a specific displacement range. This means that, when an appropriate amount of pressing force is provided such that the load control portion 230 for elements is deformed within the specific displacement range, uniform contact pressure can be applied between the new element 22 and the substrate 10.

Accordingly, even when the new element 22 is subjected to a strain d3, which can cause the new element 22 to reach a critical damage load F2 thereof, upon receiving pressing force due to machining errors of each component of the element transfer stamp 200, assembly errors between various components including thickness errors of the new element 22, or load control errors that may occur during control of load applied to the new element 22, it is possible to prevent damage to the new element if the load control portion 230 for elements provides a zero-stiffness load F1 smaller than the critical damage load F2 of the new element 22.

Referring back to FIG. 2 and FIG. 3, the element transfer stamp 200 may include a first pressing force providing portion 210 and a first pressing portion 220.

The first pressing force providing portion 210 may be disposed on an upper surface of the load control portion 230 for elements and may provide downward pressing force to the load control portion 230 for elements.

The first pressing portion 220 may be disposed on a lower surface of the load control portion 230 for elements and may press the new element 22 against the new bonding material 21 on the substrate 10.

Although the load control portion 230 for elements is shown as being entirely disposed between the first pressing force providing portion 210 and the first pressing portion 220, it should be understood that the present invention is not limited thereto and the load control portion 230 for elements may be partially disposed between the pressing force providing portion 210 and the first pressing portion 220. When the load control portion 230 for elements is partially disposed between the first pressing force providing portion 210 and the first pressing portion 220, it is desirable that the load control portion 230 be positioned to be symmetric with respect to a central axis of the element transfer stamp 200.

In addition, although the load control portion 230 for elements is shown as being positioned such that the base 231 closely contacts an upper surface of the first pressing portion 220 and the plate 237 closely contacts a lower surface of the first pressing force providing portion 210, it should be understood that the present invention is not limited thereto and the load control portion 230 for elements may be positioned such that the base 231 closely contacts the lower surface of the first pressing force providing portion 210 and the plate 237 closely contacts the upper surface of the first pressing portion 220.

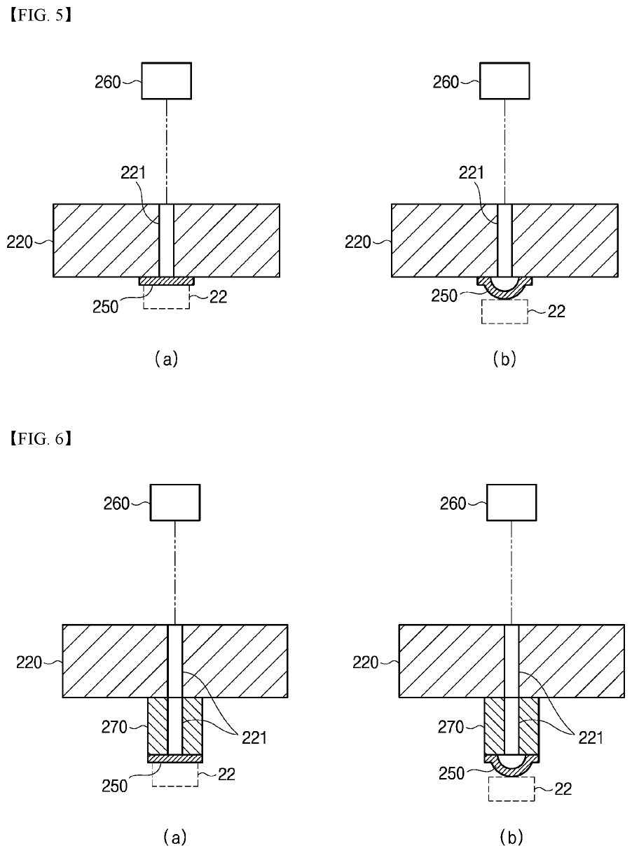

FIG. 5 is a schematic view illustrating an example of the element transfer stamp of FIG. 2.

Referring to FIG. 5, the element transfer stamp 200 may further include a fluid inlet 221, an elastic layer 250, and a flow rate control portion 260.

The fluid inlet 221 may be formed in the element transfer stamp 200 to allow a fluid supplied from an exterior to pass through the element transfer stamp 200. The fluid inlet 221 may be provided in the form of a through-hole. Specifically, the fluid inlet 221 may be formed through the first pressing portion 220 such that the fluid can be discharged below the first pressing portion 220. The fluid may include a gas or a liquid.

The elastic layer 250 may be inflated downward by the fluid introduced through the fluid inlet 221. The elastic layer 250 may be disposed on the lower surface of the first pressing portion 220 to cover the fluid inlet 221. Accordingly, when the fluid introduced through the fluid inlet 221 is discharged from the fluid inlet 221, the elastic layer 250 may be inflated by the fluid.

In addition, the elastic layer 250 may have adhesive strength such that the new element 22 is adhesively attached to a lower surface of the elastic layer 250. An area over which adhesion between the elastic layer 250 and the new element 22 occurs may be controlled through regulation of the degree of inflation of the elastic layer 250. When adhesion between the elastic layer 250 and the new element 22 occurs over a larger area, larger pressing force is applied to the new element 22 and, when adhesion between the elastic layer 250 and the new element 22 occurs over a smaller area, smaller pressing force is applied to the new element 22.

In another embodiment, once the elastic layer 250 is inflated to a certain degree by the fluid supplied thereto, the shape of the elastic layer 250 does not change regardless of the pressure of the fluid. With the elastic layer 250 inflated to the certain degree, when the pressure of the fluid is high, large pressing force is applied to the new element 22 by the elastic layer 250 and, when the pressure of the fluid is low, small pressing force is applied to the new element 22 by the elastic layer 250.

Since the elastic layer 250 elastically presses the new element 22, use of the elastic layer 250 is effective in preventing damage to the upper surface of the new element 22, such as scratches, as compared with when the pressing portion formed of a hard material directly presses the new element 22.

The flow rate control portion 260 may control a flow rate of the fluid through the fluid inlet 221. In this way, the flow rate control portion 260 can control adhesion between the elastic layer 250 and the new element 22.

FIG. 6 is a schematic view of another example of the element transfer stamp of FIG. 2.

Referring to FIG. 6, the element transfer stamp 200 may further include a protruding head 270. The protruding head 270 may protrude from the lower surface of the first pressing portion 220 and the fluid inlet 221 may extend through the protruding head 270. In addition, the elastic layer 250 may be disposed on a lower surface of the protruding head 270.

Since the protruding head 270 increases a distance between the elastic layer 250 and the first pressing portion 220, it is possible to prevent the first pressing portion 220 of the element transfer stamp 200 from pressing and damaging normal elements 12 already mounted around the repair area RA when the element transfer stamp 200 approaches the substrate 10 to transfer the new element 22 to the substrate 10.

The apparatus for repairing elements may further include a reflow stamp 300. The reflow stamp 300 may be disposed to one side of the element transfer stamp 200. The substrate 10 having the new element 22 transferred thereto may be moved under the reflow stamp 300 by the stage 900.

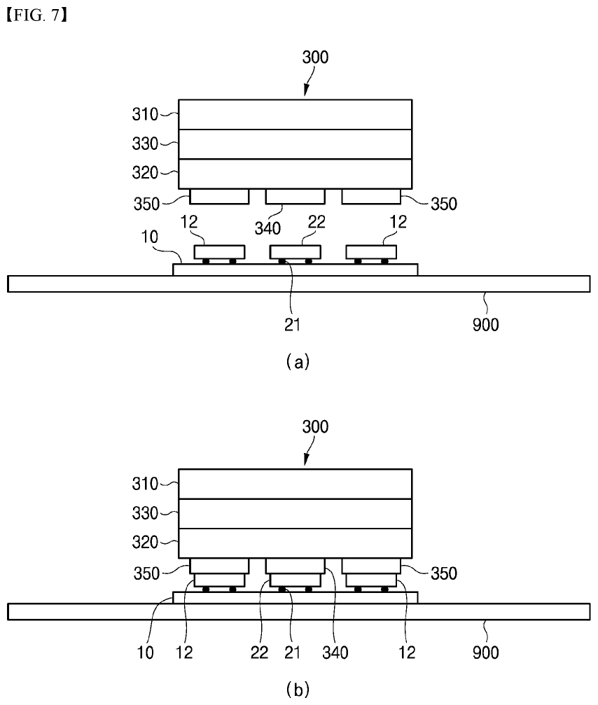

FIG. 7 is a schematic view of the apparatus for repairing elements according to the first embodiment of the present invention, focusing on the reflow stamp.

Referring to FIG. 7, the reflow stamp 300 may press and heat the new element 22 to bond the new element 22 to the new bonding material 21.

The reflow stamp 300 may include a second pressing force providing portion 310 and a second pressing portion 320.

The second pressing force providing portion 310 may provide downward pressing force.

The second pressing portion 320 may press the new element 22 on the substrate 10 by receiving pressing force from the second pressing force providing portion 310.

In addition, the reflow stamp 300 may include a pressure heater 340 and a buffer layer 350.

The pressure heater 340 may heat the new element 22 and the new bonding material 21 while pressing the new element 22. The pressure heater 340 may be disposed on a lower surface of the second pressing portion 320.

The buffer layer 350 may be disposed around the pressure heater 340. The buffer layer 350 may be disposed on the lower surface of the second pressing portion 320. The buffer layer 350 may be brought into close contact with elements 12 around the new element 22 when the pressure heater 340 presses the new element 22. The buffer layer 350 closely contacting the elements 12 can protect the elements 12 by preventing a load sufficient to cause damage to the elements 12 from being transferred to the elements 12.

In addition, the reflow stamp 300 may include a load control portion 330 for reflow. The load control portion 330 for reflow may be disposed between the second pressing force providing portion 310 and the second pressing portion 320. Upon application of pressing force, the load control portion 330 for reflow may be bent and deformed such that a zero-stiffness load smaller than a critical damage load of the new element 22 can be applied to the new element 22. The load control portion 330 for reflow may have the same configuration as the load control portion 230 for elements (see FIG. 2).

Here, the zero-stiffness load generated by the load control portion 330 for reflow may be smaller than the zero-stiffness load generated by the load control portion 230 for elements.

Since the new bonding material 21 is heated and becomes viscous during the reflow process, the new element 22 can be sufficiently pressed against the new bonding material 21 with pressing force smaller than pressing force applied to the new element 22 during the process of transferring the new element 22 to the new bonding material 21 using the element transfer stamp 200.

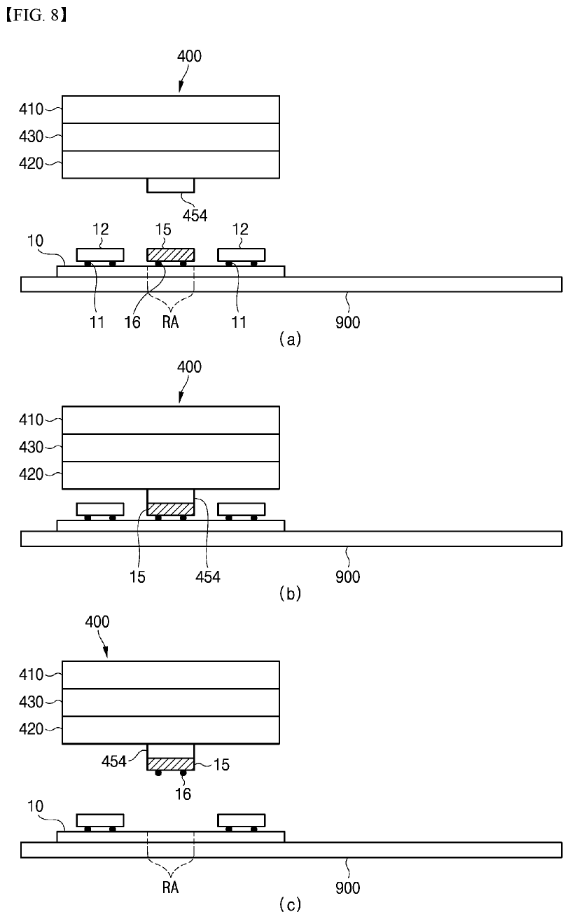

FIG. 8 is a schematic view of an apparatus for repairing elements according to a second embodiment of the present invention, focusing on a removal stamp thereof. Among the aforementioned types of defective transfer of an element to a substrate, the apparatus for repairing elements according to this embodiment may be used when the element transferred to the substrate is not accurately aligned with a bonding material, when damage to the element has occurred, or when electrical connection between the element and the bonding material is poor.

Since the apparatus for repairing elements according to this embodiment is substantially the same as the apparatus for repairing elements according to the first embodiment except that the apparatus for repairing elements according to this embodiment further includes a removal stamp 400, redundant description thereof will be omitted.

Referring to FIG. 8, the removal stamp 400 may remove a defective element 15 on a substrate 10 and a residual bonding material 16 remaining after removal of the defective element 15. That is, the removal stamp 400 may remove both the defective element 15 on the substrate 10 and the residual bonding material 16 remaining in a repair area RA with the defective element 15 removed therefrom.

The removal stamp 400 may include a pad 454. The pad 454 may include multiple pads and a selected one 454 of the multiple pads may be adhesively attached to the defective element 15.

The removal stamp 400 may include a third pressing force providing portion 410 and a third pressing portion 420.

The third pressing force providing portion 410 may provide downward pressing force.

The third pressing portion 420 may receive pressing force from the third pressing force providing portion 410, and the pad 454 may be pressed against the defective element 15 by pressing force of the third pressing portion 420.

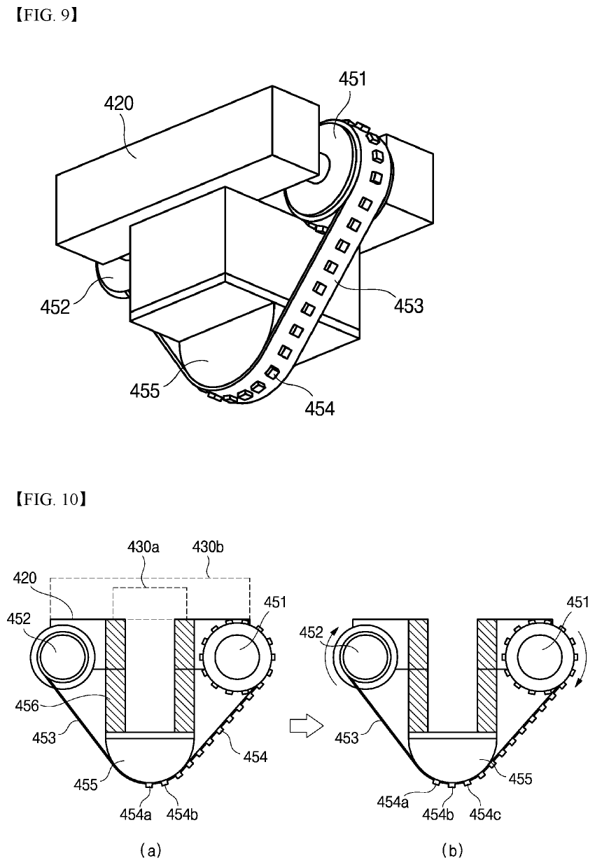

FIG. 9 is a schematic view of an example of the removal stamp of FIG. 8, and FIG. 10 is a schematic view illustrating an exemplary operation of the removal stamp of FIG. 8.

Referring further to FIG. 9 and FIG. 10, the removal stamp 400 may include a tape 453 and a pressing head 455. The tape 453 may be connected to a pair of rollers 451, 452 spaced apart from each other. The tape 453 may be wound around the second roller 452 while being unwound from the first roller 451.

The multiple pads 454 may be attached in a row to the tape 453. Specifically, the multiple pads 454 may be attached to a lower surface of the tape 453 unwound from the first roller 451 and may protrude downward.

The pressing head 455 may be disposed on an upper surface of the tape 453 to be vertically movable. To this end, the pressing head 455 may be provided on an upper surface thereof with a lifting block 456. The pressing head 455 may be vertically moved in conjunction with vertical movement of the lifting block 456.

The removal stamp 400 may include a load control portion 430 for removal. The load control portion 430 for removal may be disposed between the third pressing force providing portion 410 and the third pressing portion 420.

When the removal stamp is configured such that the lifting block 456 is vertically moved with the third pressing portion 420 remaining in a stationary state, a load control portion 430a for removal may be disposed between the third pressing force providing portion 410 and an upper surface of the lifting block 456. The load control portion 430a for removal may be bent and deformed upon receiving pressing force from the third pressing force providing portion 410 such that a zero-stiffness load smaller than a critical damage load of the defective element 15 is transferred to the lifting block 456. As a result, the pressing head 455 can apply the zero-stiffness load smaller than the critical damage load of the defective element 15 to the defective element 15.

Alternatively, when the removal stamp is configured such that the third pressing portion 420 is vertically moved in conjunction with vertical movement of the lifting block 456, a load control portion 430b for removal may be disposed between the third pressing force providing portion 410 and both the upper surface of the lifting block 456 and the upper surface of the third pressing portion 420. The load control portion 430b for removal may be bent and deformed upon receiving pressing force from the third pressing force providing portion 410 such that a zero-stiffness load smaller than a critical damage load of the defective element 15 is transferred to both the lifting block 456 and the third pressing portion 420. As a result, the pressing head 455 can press the tape 453 downward with the zero-stiffness load smaller than the critical damage load of the defective element 15 such that one of the multiple pads attached in a row to the tape 453 can be pressed against the defective element 15.

Each pad 454 is usable for one defective element 15. Since a pad used to remove one defective element 15 is not reusable, a new pad 454 needs to be positioned at a lower center of the pressing head 455 in order to remove another defective element 15. In this embodiment, after using one pad 454a to remove one defective element 15, the first roller 451 and the second roller 452 may be rotated to feed the tape such that a new pad 454b is positioned at the lower center of the pressing head 455, as shown in FIG. 10(a). After removing another defective element using the pad 454b, the tape 453 may be fed again to use a new pad 454c. The load control portion 430 for removal may have the same configuration as the load control portion 230 for elements (see FIG. 2).

The bonding material transfer stamp 100 (see FIG. 1) may also adopt the configuration described in FIG. 9 to place a new bonding material on the repair area. That is, the bonding material transfer stamp 100 may further include: the tape described above having new bonding materials, instead of the pads, attached in a row to a lower surface thereof; and a pressing head pressing one of the new bonding materials against the repair area to transfer the new bonding material to the repair area.

In addition, the element transfer stamp 200 (see FIG. 2) may adopt the configuration described in FIG. 9 to place a new element on a new bonding material. That is, the element transfer stamp 200 may further include the tape described above having new elements, instead of the pads, attached in a row to a lower surface thereof; and a pressing head pressing one of the new elements against a new bonding material to transfer the new element to the new bonding material. Here, it is obvious that the element transfer stamp 200 may include the load control portion for elements instead of the load control portion for removal 430a or 430b described above.

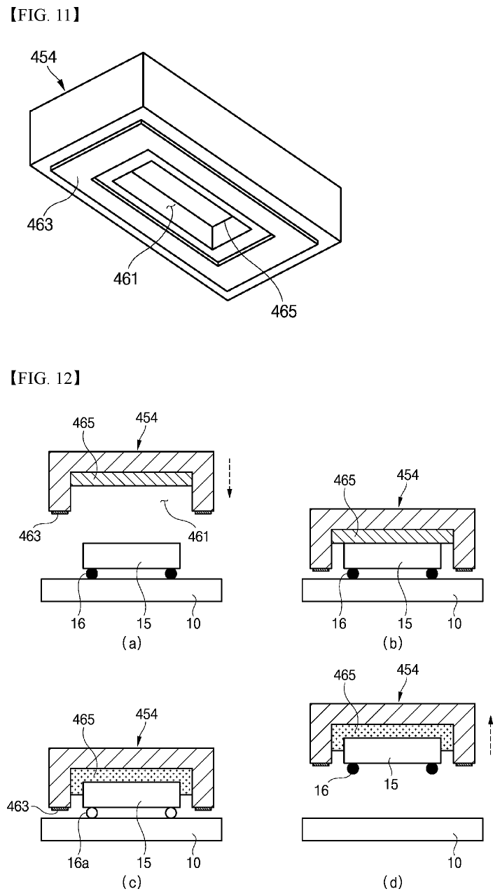

FIG. 11 is an exemplary view of the pad of FIG. 9, and FIG. 12 is a schematic view illustrating an exemplary operation of the pad of FIG. 11.

Referring to FIG. 11 and FIG. 12, the pad 454 may include a receiving groove 461, a heater 463, and an adhesive layer 465.

The receiving groove 461 may be formed on a lower surface of the pad 454 to receive a defective element 15 therein.

The heater 463 may be disposed around the receiving groove 461. The heater 463 may be disposed on the lower surface of the pad 454.

The adhesive layer 465 may be disposed in the receiving groove 461. The adhesive layer 465 may be heated by the heater 463 to allow the defective element 15 in the receiving groove 461 to be adhesively attached thereto. The adhesive layer 465 may be a thermosetting polymer that hardens when heated to a temperature higher than or equal to a curing temperature thereof, or may be a thermoplastic polymer that melts when heated and hardens again when cooled.

When the pad 454 is moved downward and the defective element 15 is inserted into the receiving groove 461, the defective element 15 may contact the adhesive layer 465 (see FIG. 12(a) and see FIG. 12(b)).

Then, when the heater 463 generates heat, the adhesive layer 465 may be heated and melted and the defective element 15 may be inserted into the adhesive layer 465 by downward load of the pad 454 (see FIG. 12(c)). When a thermosetting adhesive layer is used, the defective element 15 can be firmly secured to the adhesive layer 465 as the adhesive layer 465 is cured by heating. When a thermoplastic adhesive layer is used, the defective element 15 can be firmly secured to the adhesive layer 465 while being inserted into the adhesive layer 465. When the heater 463 continues to heat the adhesive layer, a bonding material bonded to the defective element 15 is melted by heat transferred thereto. Here, bonding strength between the cured adhesive layer 465 and the defective element 15 is greater than bonding strength between the defective element 15 and the molten bonding material 16. Accordingly, when the pad 454 is moved upward, the defective element 15 can be removed from the substrate 10 (see FIG. 12(d)).

The heater 463 may be an induction heater. When the heater 463 is an induction heater, the bonding material 16 may be inductively heated by the heater 463. Accordingly, the adhesive layer 645 may also be heated and melted together with the bonding material 16a by heat transferred from the heater 463, whereby the defective element 15 and the bonding material 16 can be more easily removed from the substrate 10 upon moving the pad 454 upward.

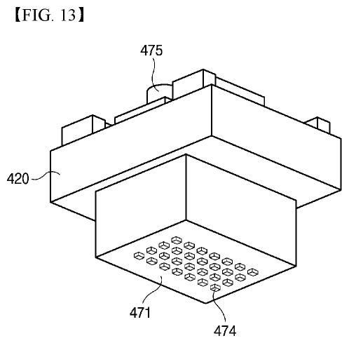

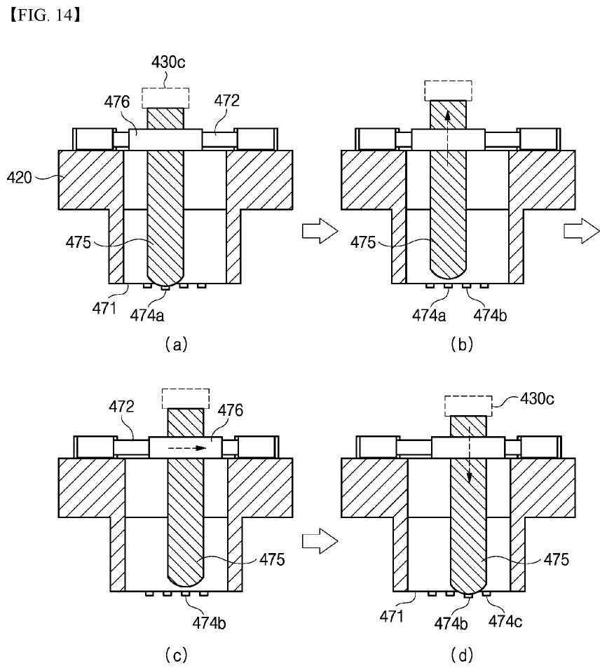

FIG. 13 is a schematic view of another example of the removal stamp of FIG. 8, and FIG. 14 is a schematic view illustrating an exemplary operation of the removal stamp of FIG. 13.

Referring to FIG. 13 and FIG. 14, the removal stamp 400 may include an attachment film 471 and a pressing rod 475.

The attachment film 471 may be positioned horizontally and may include multiple pads 474 attached in the form of an array to a lower surface thereof. The pads 474 attached to the lower surface of the attachment film 471 may protrude downward.

The pressing rod 475 may be disposed above the attachment film 471 to be horizontally movable. Specifically, the removal stamp 400 may further include a horizontal guide 472 extending in the X- and Y-axis directions in a horizontal plane and a slider 476 slidingly coupled to the horizontal guide 472 and connected to the pressing rod 475. Accordingly, the pressing rod 475 may be movable horizontally.

In addition, the pressing rod 475 may also be vertically movable above the attachment film 471.

In this embodiment, a load control portion 430c for removal may be disposed between the third pressing force providing portion 410 and an upper surface of the pressing rod 475. The load control portion 430c for removal may be bent and deformed upon receiving pressing force from the third pressing force providing portion 410 such that a zero-stiffness load smaller than a critical damage load of a defective element 15 is transferred to the pressing rod 475. As a result, the pressing rod 475 can apply the zero-stiffness load smaller than the critical damage load of the defective element 15 to the defective element 15. The pressing rod 475 may press the attachment film 471 downward such that one of the multiple pads 474 attached in the form of an array to the attachment film 471 is pressed against the defective element 15.

After one pad 474a is used to remove one defective element, the pressing rod 475 may be horizontally moved to a position over a new pad 474b. Then, the pressing rod 475 may be moved downward to remove another defective element using the pad 474b, and then may be moved horizontally again to use a new pad 474c.

The bonding material transfer stamp 100 (see FIG. 1) may also adopt the configuration described in FIG. 13 to place a new bonding material on the repair area. That is, the bonding material transfer stamp 100 may further include: the attachment film described above having multiple new bonding materials, instead of the pads, attached in the form of an array to the lower surface thereof; and a pressing rod pressing one of the multiple new bonding materials against the repair area to transfer the new bonding material to the repair area.

In addition, the element transfer stamp 200 (see FIG. 2) may also adopt the configuration described in FIG. 13 to place a new element on a new bonding material. That is, the element transfer stamp 200 may further include: the attachment film described above having multiple new elements, instead of the pads, attached in the form of an array to the lower surface thereof; and a pressing rod pressing one of the multiple new elements against a new bonding material to transfer the new element to the new bonding material. Here, it is obvious that the element transfer stamp 200 may include the load control portion for elements instead of the load control portion for removal 430c described above.

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention. For example, components described as implemented separately may also be implemented in combined form, and vice versa.

The scope of the present invention is indicated by the following claims and all changes or modifications derived from the meaning and scope of the claims and equivalents thereto should be construed as being within the scope of the present invention.

### INDUSTRIAL APPLICABILITY

The apparatus for repairing elements according to the present invention is industrially applicable to the field of element repair technology that can prevent damage to a new element during transfer of the new element and can ensure a safe repair process.

1. An apparatus for repairing elements, comprising:
a bonding material transfer stamp transferring a new bonding material to a repair area on a substrate, the repair area having a defective element or a residual bonding material removed therefrom; and
an element transfer stamp transferring a new element to the new bonding material,
wherein the element transfer stamp comprises a load control portion for elements, the load control portion being bent and deformed upon receiving pressing force such that a zero-stiffness load smaller than a critical damage load of the new element is applied to the new element.

2. The apparatus for repairing elements according to claim 1, further comprising:
a removal stamp removing the defective element on the substrate or the residual bonding material remaining after removal of the defective element.

3. The apparatus for repairing elements according to claim 2, wherein the removal stamp comprises: multiple pads contacting the defective element, one of the multiple pads being selected to be adhesively attached to the defective element.

4. The apparatus for repairing elements according to claim 3, wherein the removal stamp further comprises:
a tape having a lower surface to which the multiple pads are attached in a row, the tape being fed by a pair of rollers spaced apart from each other and connected to the tape; and
a pressing head disposed on an upper surface of the tape to be vertically movable and pressing the tape downward to press one of the multiple pads against the defective element.

5. The apparatus for repairing elements according to claim 3, wherein the removal stamp further comprises:
an attachment film having a lower surface to which the multiple pads are attached in the form of an array; and
a pressing rod disposed above the attachment film to be horizontally/vertically movable and pressing the attachment film downward to press one of the multiple pads against the defective element.

6. The apparatus for repairing elements according to claim 3, wherein the pad comprises:
a receiving groove formed on a lower surface of the pad to receive the defective element therein;
a heater disposed around the receiving groove; and
an adhesive layer disposed in the receiving groove and heated by the heater to allow the defective element received in the receiving groove to be adhesively attached to the adhesive layer.

7. The apparatus for repairing elements according to claim 6, wherein the heater is an induction heater inductively heating a bonding material electrically connecting the defective element to the substrate.

8. The apparatus for repairing elements according to claim 2, wherein the removal stamp further comprises: a load control portion for removal, the load control portion being bent and deformed upon receiving pressing force such that a zero-stiffness load smaller than a critical damage load of the defective element is applied to the defective element.

9. The apparatus for repairing elements according to claim 1, wherein the element transfer stamp further comprises:
a fluid inlet through which a fluid supplied from an exterior passes;
an elastic layer inflated downward by the fluid introduced through the fluid inlet, the elastic layer having adhesive strength; and
a flow rate control portion controlling a flow rate of the fluid through the fluid inlet to regulate adhesion between the elastic layer and the new element.

10. The apparatus for repairing elements according to claim 1, further comprising:
a reflow stamp bonding the new element to the new bonding material by pressing and heating the new element,
wherein the reflow stamp comprises: a pressure heater heating the new element and the new bonding material while pressing the new element; and a buffer layer disposed around the pressure heater, the buffer layer being brought into close contact with elements around the new element when the pressure heater presses the new element.

11. The apparatus for repairing elements according to claim 10, wherein the reflow stamp further comprises a load control portion for reflow, the load control portion being bent and deformed upon receiving pressing force such that a zero-stiffness load smaller than a critical damage load of the new element is applied to the new element.

12. The apparatus for repairing elements according to claim 1, wherein the bonding material transfer stamp comprises:
a tape having a lower surface to which multiple new bonding materials are attached in a row, the tape being fed by a pair of rollers spaced apart from each other and connected to the tape; and
a pressing head disposed on an upper surface of the tape to be vertically movable and pressing the tape downward to press one of the multiple new bonding materials against the repair area.

13. The apparatus for repairing elements according to claim 1, wherein the bonding material transfer stamp comprises:
an attachment film having a lower surface to which multiple new bonding materials are attached in the form of an array; and
a pressing rod disposed above the attachment film to be horizontally/vertically movable and pressing the attachment film downward to press one of the multiple new bonding materials against the repair area.

14. The apparatus for repairing elements according to claim 1, wherein the element transfer stamp further comprises:
a tape having a lower surface to which multiple new elements are attached in a row, the tape being fed by a pair of rollers spaced apart from each other and connected to the tape; and
a pressing head disposed on an upper surface of the tape to be vertically movable and pressing the tape downward to press one of the multiple new elements against the new bonding material.

15. The apparatus for repairing elements according to claim 1, wherein the element transfer stamp further comprises:
an attachment film having a lower surface to which multiple new elements are attached in the form of an array; and
a pressing rod disposed above the attachment film to be horizontally/vertically movable and pressing the attachment film downward to press one of the multiple new elements against the new bonding material.
